(19) United States
(12) Patent Application Publication
(10) Pub. No.: US 2020/0042888 A1
(43) Pub. Date: Feb. 6, 2020

(54) SELF-SUFFICIENT ARTIFICIAL INTELLIGENCE EDGE DEVICES

(71) Applicant: Gyrfalcon Technology Inc., Milpitas, CA (US)

(72) Inventors: Hualiang YU, San Jose, CA (US); Chyu-Jiuh Torng, Dublin, CA (US); Daniel H. Liu, San Jose, CA (US)

(73) Assignee: Gyrfalcon Technology Inc., Milpitas, CA (US)

(21) Appl. No.: 16/050,679

(22) Filed: Jul. 31, 2018

(51) Int. Cl. G06N 5/04; G06N 3/063; G11C 11/54; G06N 3/08

(52) U.S. Cl. CPC G06N 5/046; G06N 3/084; G11C 11/54; G06N 3/063

(57) ABSTRACT

This disclosure relates to a self-contained and self-sufficient edge device capable of performing processing data sets using a convolutional neural network model without relying on any backend servers. In particularly, the edge device may include non-volatile memory cells for storing a full set of trained model parameters from the convolutional neural network model. The non-volatile memory cells may be based on magnetic random access memory cells and may be embedded on the same semiconductor substrate with a convolutional neural network logic circuit dedicated to parallel forward propagation calculation.

### TECHNICAL FIELD

This disclosure generally relates to self-sufficient and standalone artificial intelligence (AI) devices requiring no support from any backend servers, and particularly relates to self-sufficient AI devices including a multilayer convolutional neural network.

### BACKGROUND

Deep learning models that are trained and deployed with convolutional neural networks (CNNs) may include many convolutional layers, pooling layers, rectification layers, and fully connected layers, and generally require millions of trained model parameters for processing complex input data such as images, speeches, and natural languages. Deployment of such a model thus requires massive amount of memory for storing the model parameters and intermediate calculation results, and further relies on large-scale parallel processing along multiple computation paths through layers of neurons. As such, trained CNN models are traditionally deployed in powerful backend servers equipped with a combination of processors and coprocessors, such as Graphics Processing Units (GPUs) with large graphics memories. An edge device such as a mobile phone and any other special purpose device (e.g., an IoT (Internet-of-Things) device) seeking AI services may only need to transmit necessary input data to and receiving processing outcome from the backend servers. Placing core AI functions completely within an edge device has been difficult without new processing and memory architectures.

### SUMMARY

This disclosure is directed to AI edge devices that do not need support from any backend servers. Further objects, features, and advantages of this invention will become readily apparent to persons of ordinary skill in the art after a review of the following description, with reference to the drawings and claims that are appended to and form a part of this specification.

In one implementation, a self-contained device is disclosed. The device may include a convolutional neural network (CNN) logic circuit; a plurality of non-volatile random access memory cells embedded with the CNN logic circuit on a same semiconductor substrate and storing a full set of trained parameters for a CNN model containing multiple neurons; a sensor; an actuator circuitry; a program memory storing instructions; and a microcontroller unit in communication with the program memory, the sensor, the CNN logic circuit, the plurality of non-volatile random access memory cells, and the actuator circuitry. The microcontroller unit, when executing the instructions in the program memory, may be configured to cause the sensor to detect a signal according an external stimulus; process the detected signal to obtain a processed data set and communicate the processed data set to the CNN logic circuit; instruct the CNN logic circuit to read trained parameters from the plurality of non-volatile random access memory cells and to forward propagate the processed data set via multiple propagation paths through the multiple neurons in parallel to obtain output label data for the processed data set; process the output label data into a control signal; and control the actuator circuitry according to the control signal.

In the devices above, the plurality of non-volatile random access memory cells may include magnetic random access memory cells (MRAM cells).

In any of the devices above, at least one of the MRAM cells includes a spin torque transfer type of MRAM cell. In any of the devices above, the MRAM cells may be of at least two different cell sizes. In any of the devices above, the MRAM cells bay be arranged with at least two different pitches. In any of the devices above, a read access time for the plurality of non-volatile random access memory cells by the CNN logic circuit may be faster than 5 nanoseconds.

In any of the devices above, the plurality of non-volatile random access memory cells may be programmed with the full set of trained parameters for the CNN model at one of a wafer level, a chip level, or a printed circuit board level.

In any of the devices above, the sensor may include an image sensor and the processed data set may include at least one two dimensional array of pixel values.

Any of the devices above may further include an optical lens assembly for imaging an object field external to the device onto the image sensor. In any of the devices above, the image sensor may include a CMOS active sensor matrix. In any of the devices above, the image sensor may be integrated on the same semiconductor substrate for the CNN logic circuit with the plurality of non-volatile random access memory cells.

In any of the devices above, the CMOS active sensor matrix may be fabricated over the plurality of non-volatile random access memory cells. In any of the devices above the plurality of non-volatile random access memory cells may be fabricated over the CNN logic circuit and the CNN logic circuit may be fabricated over the same semiconductor substrate.

In any of the devices above, the CNN logic circuits and the plurality of non-volatile random access memory cells may be fabricated on different areas of the same semiconductor substrate, and the CMOS active sensor matrix may be fabricated over the CNN logic circuits and the plurality of non-volatile random access memory cells.

In any of the devices above, the plurality of non-volatile random access memory cells may include MRAM cells.

In any of the devices above, the plurality of non-volatile random access memory cells comprises MRAM cells and static random access memory (SRAM) cells.

In any of the devices above, the plurality of non-volatile random access memory cells comprises MRAM cells and resistive random access Memory (RRAM) cells.

In any of the devices above, the plurality of non-volatile random access memory cells comprises MRAM cells and phase change random access memory (PCRAM) cells.

In any of the devices above, the plurality of non-volatile random access memory cells comprises MRAM cells and at least a plurality of one time programmable (OTP) memory cells.

In another implementation, another self-contained AI device is disclosed. The device ma include a convolutional neural network (CNN) logic circuit; a memory comprising a plurality of non-volatile MRAM cells, the memory storing a set of instructions and a full set of trained parameters for a CNN model containing multiple neurons; a sensor; an actuator circuitry; and a microcontroller unit in communication with the memory, the sensor, the CNN logic circuit, and the actuator circuitry. The microcontroller unit, when executing the set of instructions in the memory, may be configured to: cause the sensor to detect a signal according an external stimulus; process the detected signal to obtain a processed data set and communicate the processed data set to the CNN logic circuit; instruct the CNN logic circuit to read trained parameters from the plurality of non-volatile MRAM cells and to forward propagate the processed data set via multiple propagation paths through the multiple neurons in parallel to obtain output label data for the processed data set; process the output label data into a control signal; and control the actuator circuitry according to the control signal.

In the device above, the plurality of non-volatile MRAM cells may be programmed with the full set of trained parameters for the CNN model at one of a wafer level, a chip level, or a printed circuit board level.

In any of the devices above, the sensor may include an image sensor and the processed data set may include at least one two dimensional array of pixel values. In any of the devices above, the image sensor may include a CMOS active sensor matrix. In any of the devices above, the image sensor may be integrated on a same semiconductor substrate for the CNN logic circuit.

### BRIEF DESCRIPTION OF THE DRAWINGS

FIG. 1 illustrates an architectural diagram of an exemplary self-Sufficient artificial intelligence edge device.

FIG. 2 shows an architectural diagram of an exemplary artificial intelligence engine with embedded memory for storing model parameters.

FIG. 3 illustrates various embedded memory configuration for an artificial intelligence engine.

FIGS. 4A-4B illustrate cross-sectional views of various implementations for embedding memories with logic circuits of an artificial intelligence engine on a same semiconductor substrate.

FIG. 5 illustrates an architectural diagram of another exemplary self-sufficient artificial intelligence edge device.

FIGS. 6A and 6B illustrate cross-sectional views of exemplary implementations for embedding memories and a CMOS image sensor with logic circuits of an artificial intelligence engine on a same semiconductor substrate.

### DETAILED DESCRIPTION

Artificial intelligence techniques have been widely used for processing large amount of input data to extract categorical information. These techniques, in turn, may then be incorporated into a wide range of applications to perform various intelligent tasks. For example, deep learning techniques based on convolutional neural networks (CNNs) may provide trained CNN models for processing particular types of input data. For example, a CNN model trained for classifying images may be used to analyze an input image and determine a category of the input image among a predetermined set of image categories. For another example, a CNN model may be trained to produce segmentation of an input image in the form of, e.g., an output segmentation mask. Such segmentation mask, for example, may be designed to indicate where human faces are, and the CNN model may be further trained to determine and recognize the segmented human face among a known set of human faces.

A deep learning CNN model, may typically contain multiple cascading convolutional, pooling, rectifying, and fully connected layers of neurons, with millions of weight and bias parameters. These parameters may be determined by training the model using a sufficient collection of labeled input data. Once a CNN model is trained and the model parameters are determined, it may be used to process unknown input data and to predict labels for the unknown input data. These labels may be classification, segmentation mask, or any other type of labels for the input data.

In a training process of a CNN model, each of a large number of labeled training data sets is forward propagated through layers of neurons of the CNN network embedded with the training parameters to calculate an end labeling loss. Back propagation is then performed through the layers of neurons to adjust the training parameters to reduce labeling loss based on gradient descent. The forward/back propagation training process for all training input data sets iterates until the neural network produces a set of training parameters that provide converging minimal overall loss for the labels predicted by the neural network over labels given to the training data sets. A converged model then includes a final set of training parameters and may then be tested and used to process unlabeled input data sets via forward propagation. Such a CNN model typically must be of sufficient size in terms of number of layers and number of neurons/features in each layer for achieving acceptable predictive accuracy. The number of training parameters is directly correlated with the size of the neural network, and is typically extraordinarily large even for a simple AI model (on the order of millions, tens of millions, hundreds of millions, and thousands of millions of parameters). The forward and back propagations thus require a massive amount of memory to hold these parameters and extensive computation power for iteratively calculating states of a massive number of neurons.

In addition, a large working memory may also be needed during training or deployment of a CNN model for holding a large amount of intermediate calculation results, such as feature maps at various convolutional layers. This working memory may be reusable and shared by non-parallel neurons or layers during forward and back propagations, and thus may be frequently written and read.

The training process for a CNN model is thus typically handled by centralized or distributed backend servers having sufficient memory and computing power in order to train the CNN model in a reasonable amount of time. These calculations may be performed by special co-processors included in the backend servers that are based on parallel data processing. For example, a Graphics Processing Unit (GPU) with large embedded memory or with external memory connected to the GPU core via high speed data buses may be included in the backend servers and used to accelerate the forward/back propagations in neural networks, thanks to similarity in parallel data manipulation between graphics data and neural networks.

Once trained, a CNN model may be deployed in the backend servers and provided as a service, taking advantage of the memory capacity and the parallel computing power of the backend servers. The service would include forward propagating an input data set through the layers of neurons of the trained CNN model to obtain an output label for the input data set. Such a service may be provided to edge devices. Edge devices may include but are not limited to mobile phones and any other devices, such as Internet-of-Things (IoT) devices. These devices may be designed to handle limited tasks and with limited computing power and memory capacity, and thus incapable of efficiently performing forward propagation locally. As such, these edge devices may communicate with the backend servers via communication network interfaces to provide input data sets to the backend servers and obtained labels for the input data sets from the backend server after the input data sets are processed by the CNN model in the backend servers.

In many applications, local processing of the input data may be desired. For example, when an input data set is large (e.g., high-resolution 2D or 3D images), transmission of the input data set from the edge device to the backend servers may consume an unacceptable or unsupported level of communication bandwidth and/or power. Further, some edge devices may have only intermittent communication network connection or no communication network connection at all.

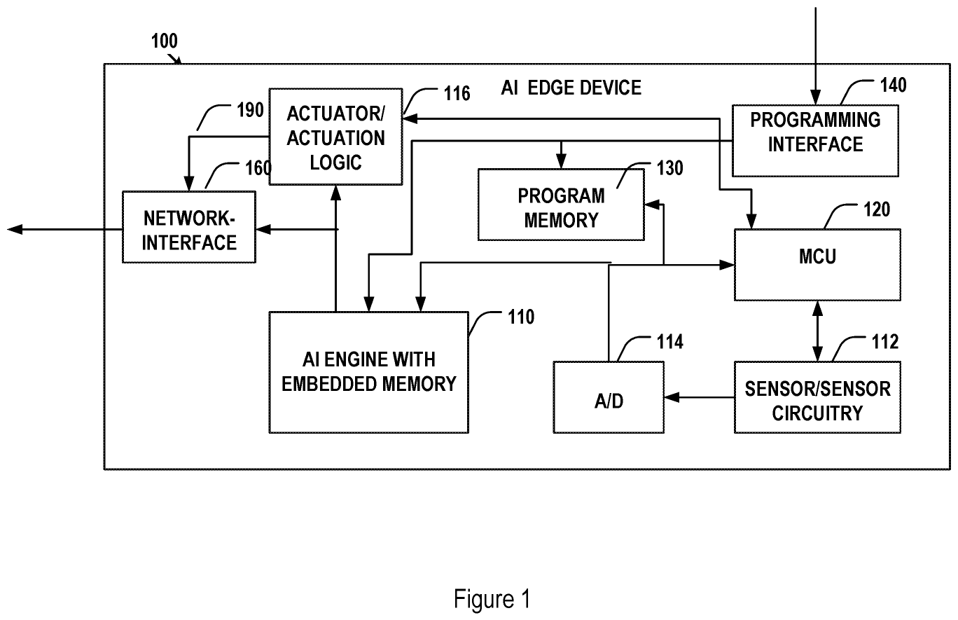

One implementation of an edge device capable of storing a CNN model and locally processing input data via forward propagation through a locally stored neural network is illustrated in FIG. 1. In particularly, the edge device 100 of FIG. 1 may include a core AI engine 110 with embedded memory, a sensor and corresponding sensor circuitry 112, an analog to digital converter circuitry 114, a microcontroller unit (MCU) 120, a program memory 130, a programming interface 140, actuators/actuation logic 116, and a communication network interface 160.

The MCU 120 acts as a central control unit of the edge device 100. Specifically, the MCU 120 may execute instructions stored in the program memory 130 to control other components in the edge device 100 to perform the functions of the entire edge device 100. The program memory 130, for example, may be a non-volatile Read-Only Memory (ROM) and may be programmed when the program memory circuitry is fabricated at wafer level or at the chip level. Alternatively, the instructions may be load into the program memory 130 after the edge device 100 is manufactured via the optional programming interface 140. The instructions may be loaded into the program memory 130 as, e.g., a firmware via the programming interface 140. In addition, the instructions loaded into the program memory 130 may be upgradable by erasing and rewrite its content via the programming interface 140. As such, the program memory may be implemented as an erasable and reprogrammable memory, such as EPROM.

The sensor and sensor circuitry 112 may be used to detect and monitor external contextual data in real-time or under the control of the MCU 120. Depending on the application of the edge device 100, the detected external environmental data may include but are not limited to images, voices, environmental temperature, humidity, barometric pressure, latitude, device orientation, device motion, lighting level. As such, the sensor may be implemented, for example, as an image sensor, a microphone, a thermometer, a hygrometer, a barometer, a GPS sensor, a gyroscope, and an optical detector. Peripheral components for the sensor 112 may be further included in the edge device 100. For example, when the sensor 112 include an image sensor (e.g., a CCD or CMOS sensor), a peripheral optics including imaging lenses may be included for creating optical images onto the image sensor for detection. Signal detected by the sensor/sensor circuitry 112, if analog, may be further converted into digital form and processed by the MCU 120 into a form compatible with a data set that may be processed by the AI engine 110.

The processed sensor data may then be provided to the AI engine 110 for forward propagation under the general control of the MCU 120. The AI engine 110 may be embedded with memory for storing trained model parameters and any intermediate data that may need to be stored during the forward propagation process. The memory for storing model parameters (such as parameters for the convolutional layers and full connected layers with hidden layers) and the working memory for storing intermediate calculation results such as feature maps maybe be the same type or different types of memories, as will be described in more detail below.

The trained model parameters may be loaded into the embedded memory of the AI engine 110 at the time of manufacturing of the AI engine chip, at the time of manufacturing the edge device 100, or loaded via the programming interface 140 and the MCU 120. If needed, the trained model parameters may be updated by reloading a new version of training parameters into the embedded memory of the AI engine 110 via the programming interface 140 and the MCU 120. The output of the AI engine may be a predictive label for the input data set. Such an output may be provided to the actuator/actuation logic 116 to provide actuation of a desired control. Alternatively, the output label of the AI engine 110 may be converted into a control signal 190 or into a signal that is transmitted into the communication network via the network interface 160. Alternatively, the output of the AI engine may be processed by the MCU 120 and the processed data may then be communicated to the actuator and actuation logic circuit 116. The actuator 116 may be used for producing desired action according to the outcome of the AI engine 110. The actuation performed by the actuator 116 may be any type including but not limited to electric, mechanical, thermal, magnetic, and hydraulic. In some implementations, the actuator may be external to the edge device 100, as such, the actuator circuitry 116 may provide a signal 190 and the edge device may transmit the actuator signal 190 to the external actuator via the network interface 160.

The arrows and lines in FIG. 1 connecting various components of the device 100 are merely exemplary. In some other implementations, components that are not connected with arrows and lines may communicate to one another as needed, under the control of the MCU 120.

The edge device 100 of FIG. 1 may be designed for various applications. For example, the edge device 100 may be a traffic monitor that may be disposed on roadside or at a traffic control point. Such a traffic monitor may include an image sensor for taking images and analyzing the images to obtain traffic information using a CNN model stored in the traffic monitor. The results of the analysis may be used to generate control signal to traffic lights. For another example, the edge device may be implemented as a security device at an entry control point. Such a security device may include an image sensor for taking picture of a person approaching the entry control point. The device may include a CNN model for face recognition and for determine whether the detected image contains a human face associated with someone having entry authorization. The device may further trigger an actuator to open a door at the entry control point to let the person in. By using the implementations provided in this disclosure for these applications and the like, no network communication to any remote backend servers are needed. The edge device is capable of performing pre-stored AI functions with self-sufficiency. These devices thus can be deployed anywhere.

The edge device 100 may include more than one AI models. As such, the embedded memory of the edge device may store parameters for multiple AI models and may function as working memory for forward propagation of the multiple AI models. For example, the edge device may be used to detect both images and voices and control the actuator based on both image and voice recognition. As such, the edge device 100 may include at least two different AI models (e.g., different CNN models) including at least one model for image analysis and recognition and another model for speech analysis and voice recognition. The embedded memory for the edge device 100 thus would be configured to hold parameters for both models. The embedded memory may further function as working memory for both models.

As discussed above, processing of input data by a CNN model usually requires a large amount of memory (for model parameters and for intermediate calculation results) and parallel processing capability for forward propagation. In real-time applications, there may be further processing speed requirement that places stringent limitation on the communication speed between the logic circuits of the CNN and the memory for storing the training parameters and intermediate calculation results. Further, the memory for storing the training parameters of the CNN model is preferably non-volatile, as it serves as the only repository for these parameters in the edge device 100. The working memory for storing intermediate results may be preferably fast and durable as the working memory may be frequently written and read. In the implementation for the edge device 100 of FIG. 1, the AI logic circuits may be embedded with one or more types of memories that satisfies the need of both the parameter memory and working memory.

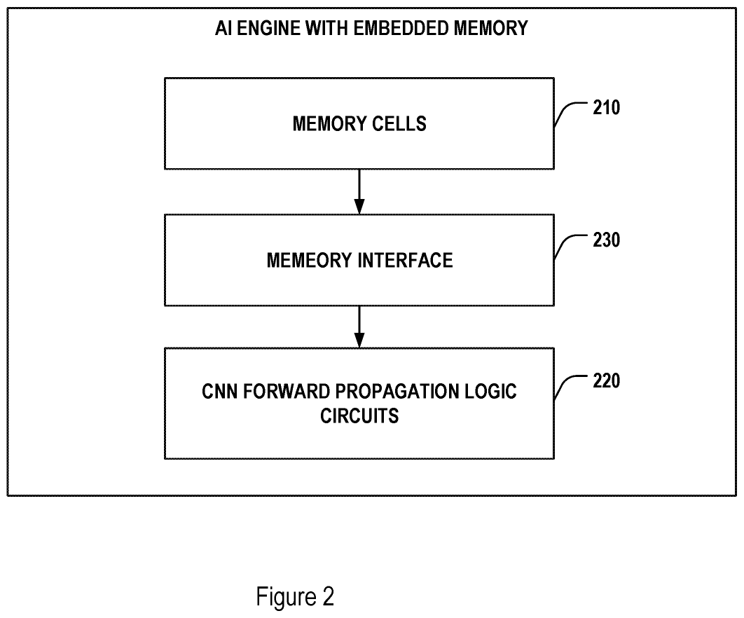

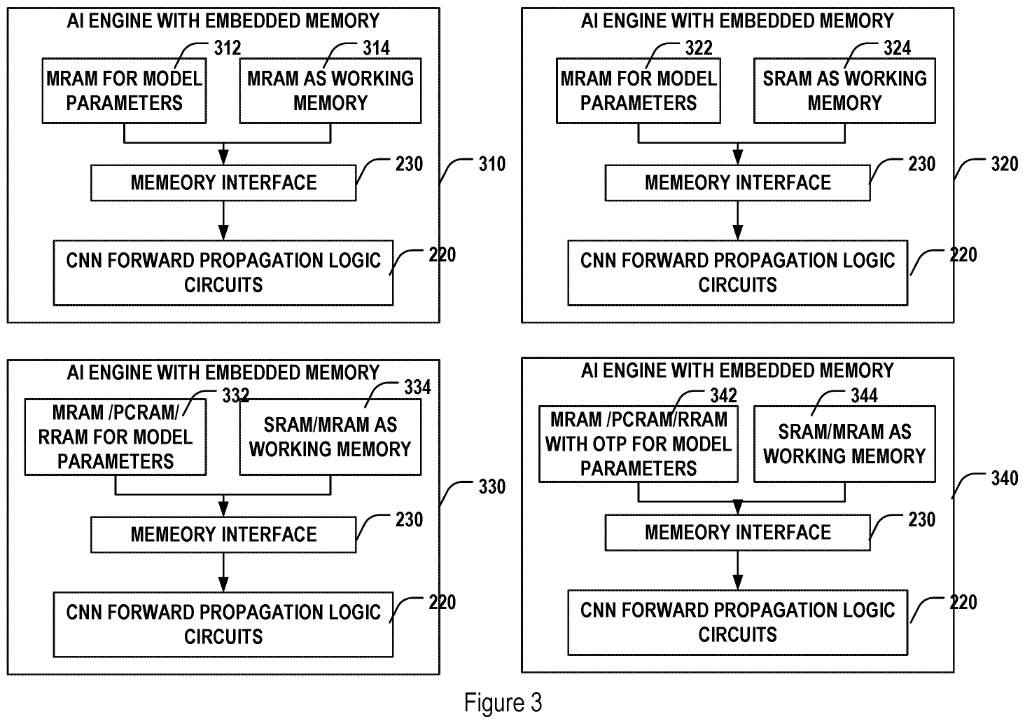

As illustrated in FIG. 2, the embedded memory may be implemented as memory cells 210 imbedded with the AI engine or CNN logic circuits 220. In some implementations, an embedded memory interface 230 may be used to facilitate the data access by the AI logic circuits 220. The AI logic circuits may be specifically designed to provide parallel processing of various forward propagating paths through the layers of neurons of the CNN network. The memory cells 210 may be a single type or mixed types of memories, as shown by various implementations illustrated in FIG. 3.

In some implementations, as shown by 310 of FIG. 1, the memory cells for both the model parameter memory 312 and working memory 314 may be based on magnetic random access memory (MRAM) technologies. The MRAM cells 312 and 314 may be integrated with AI logic circuits 220 dedicated for the CNN forward propagation calculation on a same semiconductor substrate in a single chip configuration. The single-chip AI engine with embedded MRAM 312 and 314 may be fabricated based on a CMOS fabrication technology. The model parameter MRAM 312 and working MRAM 314 may be formed on separate areas on the AI chip or maybe mixed in an integral area on the AI chip. Exemplary implementation for integrating CNN logic circuits and MRAM may be found in U.S. patent application Ser. No. 15/989,515, U.S. patent application Ser. No. 15/838,131, U.S. patent application Ser. No. 15/726,084, U.S. patent application Ser. No. 15/642,100, and U.S. patent application Ser. No. 15/642,076 by the same Applicant as the current application, which are incorporated herein by reference in their entireties. For example, the embedded MRAM cells may be based on spin torque transfer (STT) type of magnetic tunnel junctions (MTJs). Each MRAM memory cell may include a MTJ layer and a dielectric layer. The MTJ layer may include a magnetic tunnel layer sandwiched between a pined layer and a free layer. The free layer of the MTJ layer may comprise CoₓFe_{y}B_{z}, FeₓB_{y}, FeₓB_{y}/CoₓFe_{y}B_{z}, CoₓFe_{y}B_{z}/CoₓFe_{y}B_{z}, CoₓFe_{y}B_{z}/M/CoₓFe_{y}B_{z}, FeₓB_{y}/M/FeₓB_{y} or FeₓB_{y}/CoₓFe_{y}B_{z}/M/CoₓFe_{y}B_{z}, wherein M is metal. The MTJ layer may be etched and filled with dielectric materials between MTJs. In some implementations, the STT MRAM memory may also include a bit layer formed on top of the MTJ layer, such as over the free layer of the MTJ layer. Additionally, the STT memory may include a passivation layer and a bond pad (now shown), as known in the IC industry. These MRAM cells may be designed to achieve read access time faster than 10 nanosecond, faster than 5 nanosecond, or faster than 2 nanosecond. These MRAM cells may further be designed with high density and small cell size. For a MRAM cell, the MTJ may be formed with a width raging from 20 nm to 200 nm.

In some other implementations, as shown in 320 of FIG. 3, the model parameter memory 322 may be implemented as embedded MRAM whereas the working memory 324 may be implemented as embedded static random access memory (SRAM). In particular, MRAM in this implementation provides non-volatile storage and fast access of model parameters. The SRAM provides working memory cells for storing intermediate calculation results. MRAM may have larger capacity than SRAM and thus may be suitable for holding the large amount of model parameters, particular in the situation where more than one CNN model is included in the edge device and thus the capacity requirement for storing model parameters are even greater.

In some other implementations, as shown in 330 of FIG. 3, the model parameter memory 332 may be implemented as embedded MRAM, phase change random access memory (PCRAM), resistive random access memory (RRAM), or any combination thereof. Different types of memory may be used for different types of model parameters. The working memory 334 may be implemented as MRAM, SRAM, or a combination thereof for storing different types of intermediate calculation results.

In yet some other implementations, as shown in 340 of FIG. 3, the model parameter memory 343 may be implemented as MRAM, PCRAM, RRAM, or any combination thereof, including some amount of one time programmable (OTP) memory cells. The OTP memory cells may be implemented using, e.g., a special type of RRAM or other one time programmable memory technologies. In particular, some of the model parameter memory cells may be implemented as OTP such that these parameters cannot be changed or reprogrammed once they are initially programmed. Such implementations may be used in security applications where the CNN model cannot be tapered with. In these implementations, the working memory 344, again, may be implemented as MRAM, SRAM, or a combination thereof for storing different types of intermediate calculation results.

Implementations of RRAM in OTP configuration or any other configurations are described in U.S. patent application Ser. No. 15/989,515 by the same applicant as the current application, which is herein incorporated by reference in its entirety.

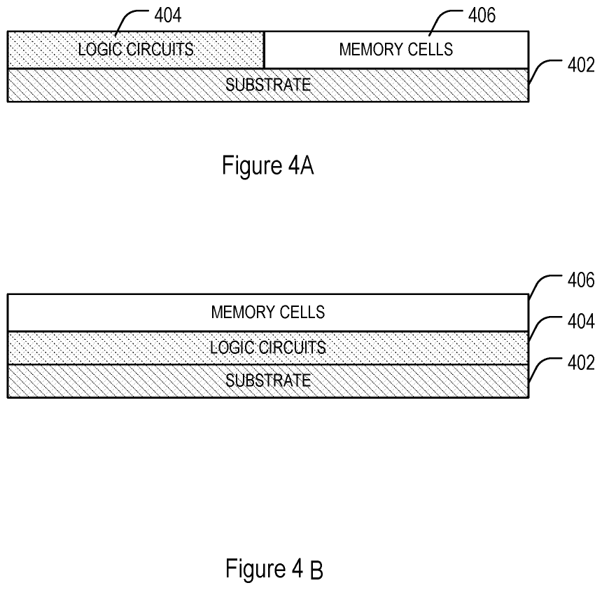

Embedding memories cells with the CNN logic circuits 220 may be implemented as shown in FIGS. 4A-3B. In particular, FIGS. 4A-4B illustrate cross-sectional views of a single-chip AI engine having CNN logic circuits 304 embedded with memory cells 306 fabricated on the same semiconductor substrate 402. In one implementation as shown in FIG. 4A, the CNN logic circuits 404 and the memory cells 406 may be fabricated on separate portions of the semiconductor substrate 402. The interconnection between the logic circuits 404 and the memory cells 406 may be provided by metal lines that are disposed either on top of the logic circuits and memory cell structures or as interlayer metal lines.

Alternatively, as shown in FIG. 4B, the memory cells 406 and the CNN logic circuits 404 may be fabricated as separate layered structures on the semiconductor substrate 402. For example, memory cells 406 may be fabricated on top of the CNN logic circuits 404. Interconnection between the memory cells and elements of the CNN logic circuits 404 may be provided directly using various metal vias or using metal vias in combination with one or more interlayer metal line.

In FIGS. 4A and 4B, the memory cells 406 may be a single type of memory cells (MRAM, SRAM, PCRAM, RRAM, for example) or may be a mix of multiple types of memory cells. The different types of memory cells may be spatially segregated or may be mixed or interlaced. Further, in FIG. 4B, for example, different types of memory cells may be implemented as multiple sublayers of the memory cell layer 406.

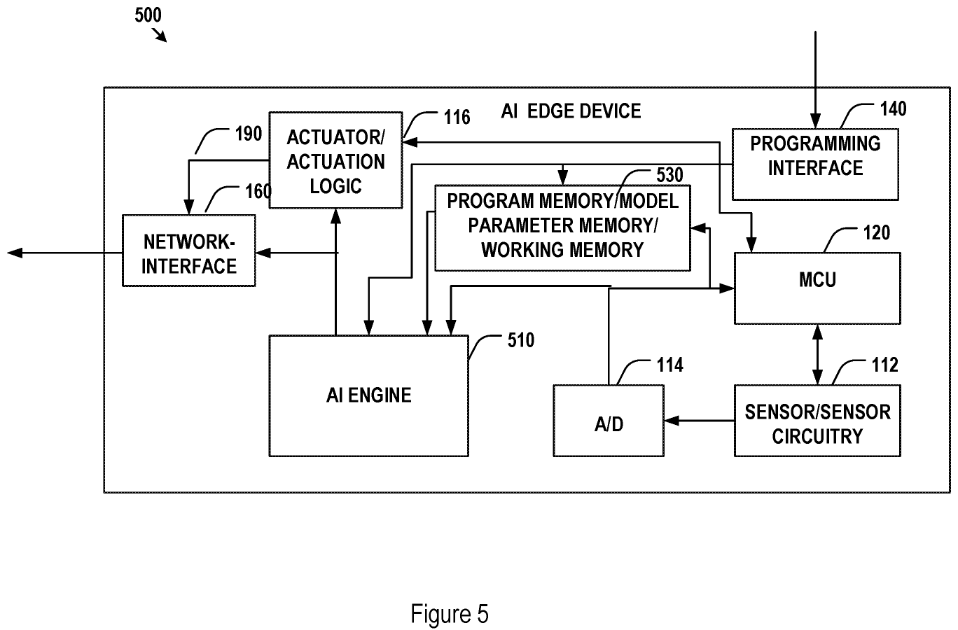

FIG. 5 shows another implementation 500 for the edge device alternative to FIG. 1. In the implementation of FIG. 5, the program memory 130 of FIG. 1 may be alternatively implemented as a memory chip 530 which stores both the firmware for execution by the MCU 120 for controlling the operation of the edge device, and the model parameters and intermediate results for the CNN model. As such, the AI engine 110 with embedded memory in FIG. 1 may be implemented as an AI engine 510 with only CNN logic circuits configured for performing parallel forward propagation by reading the model parameters and reading/writing intermediate results from or to the memory chip 530. The firmware and model parameters may be programmed into the memory chip at wafer level during the fabrication process of the memory dies. They may be alternatively programmed into the memory chip at chip level when each memory chip being processed, tested, or packaged. They may also be alternatively programmed into the memory chip at a printed circuit board level after the memory chip is placed onto a circuit board of the edge device. The communication interface between the memory chip 530 and the AI engine 510 may be made sufficiently wide to support high speed data transfer, e.g., data transfer speed at tens or hundreds of gigabytes per second. The memory chip 530 may be include a single type of memory cells or memory cells of mixed types, as discussed above. Other components of the implementation 500 for the edge device in FIG. 5 are similar to those corresponding components in the implementation 100 for the edge device in FIG. 1 and are not duplicatively described herein.

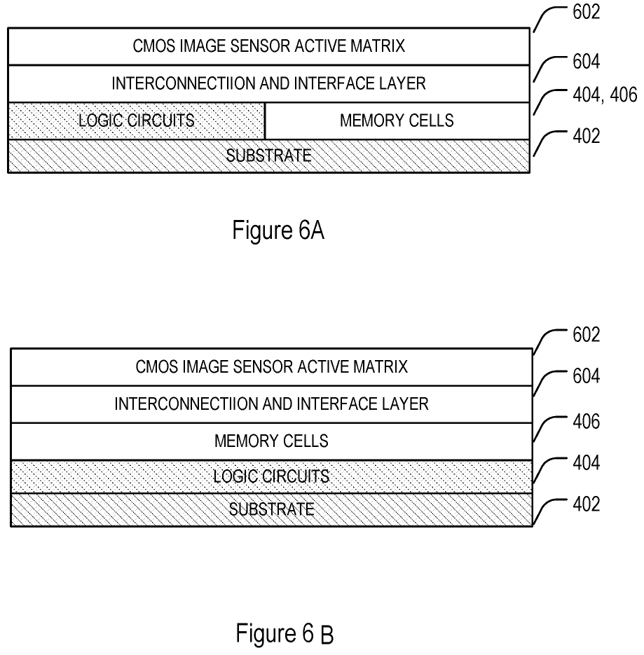

FIG. 6 shows cross-sectional views of some other implementations for integrating the sensor/sensor circuitry 112 and the AI engine 110 with embedded memory cells onto a same semiconductor substrate. In particular, as shown in FIG. 6, when the sensor/sensor circuitry of the edge device 100 includes an image sensor and corresponding circuitry, the sensor/sensor circuitry 112 may be implemented based on CMOS technologies and integrated with the AI engine 110 with embedded memory. In both the implementations of FIGS. 6A and 6B, the CMOS image sensor layers 602 (e.g., CMOS image sensor active matrix) are fabricated on top of the AI engine with embedded memory cells for facilitating efficient reception of light collected by a camera lens assembly from an object field being imaged. FIG. 6A and FIG. 6B particularly illustrate cross-sectional views of configurations for integrating the CMOS sensor according to the embedded memory configurations of FIG. 4A and FIG. 4B, respectively. In some implementations, an interconnection and interface layer 604 may be included to between the CMOS image sensor layers 602 and the memory cells layer 406 (in FIG. 6B) or memory cells layer 406 and AI logic circuits layer 404 (in FIG. 6A).

The description and accompanying drawings above provide specific example embodiments and implementations. Drawings containing circuit and system layouts, cross-sectional views, and other structural schematics, for example, are not necessarily drawn to scale unless specifically indicated. Subject matter may, however, be embodied in a variety of different forms and, therefore, covered or claimed subject matter is intended to be construed as not being limited to any example embodiments set forth herein. A reasonably broad scope for claimed or covered subject matter is intended. Among other things, for example, subject matter may be embodied as methods, devices, components, or systems. Accordingly, embodiments may, for example, take the form of hardware, software, firmware or any combination thereof.

Throughout the specification and claims, terms may have nuanced meanings suggested or implied in context beyond an explicitly stated meaning. Likewise, the phrase “in one embodiment/implementation” as used herein does not necessarily refer to the same embodiment and the phrase “in another embodiment/implementation” as used herein does not necessarily refer to a different embodiment. It is intended, for example, that claimed subject matter includes combinations of example embodiments in whole or in part.

In general, terminology may be understood at least in part from usage in context. For example, terms, such as “and”, “or”, or “and/or,” as used herein may include a variety of meanings that may depend at least in part on the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

Reference throughout this specification to features, advantages, or similar language does not imply that all of the features and advantages that may be realized with the present solution should be or are included in any single implementation thereof. Rather, language referring to the features and advantages is understood to mean that a specific feature, advantage, or characteristic described in connection with an embodiment is included in at least one embodiment of the present solution. Thus, discussions of the features and advantages, and similar language, throughout the specification may, but do not necessarily, refer to the same embodiment.

Furthermore, the described features, advantages and characteristics of the present solution may be combined in any suitable manner in one or more embodiments. One of ordinary skill in the relevant art will recognize, in light of the description herein, that the present solution can be practiced without one or more of the specific features or advantages of a particular embodiment. In other instances, additional features and advantages may be recognized in certain embodiments that may not be present in all embodiments of the present solution.

From the foregoing, it can be seen that this disclosure provides a semiconductor chip architecture including logic circuits embedded with various types of memories for improving memory access speed and reducing power consumption. In particular, memories of distinct types embedded with logic circuits on a same semiconductor substrate are disclosed. These memories may include static random access memory, magnetoresistive random access memory, and various types of resistive random access memory. These different types of memories may be combined to form an embedded memory subsystem that provide distinct memory persistency, programmability, and access characteristics tailored for storing different type of data in, e.g., application involving convolutional neural networks.

What is claimed is:

1. A self-contained device, comprising:
a convolutional neural network (CNN) logic circuit;
a plurality of non-volatile random access memory cells embedded with the CNN logic circuit on a same semiconductor substrate and storing a full set of trained parameters for a CNN model containing multiple neurons;
a sensor;
an actuator circuitry;
a program memory storing instructions; and
a microcontroller unit in communication with the program memory, the sensor, the CNN logic circuit, the plurality of non-volatile random access memory cells, and the actuator circuitry,
wherein the microcontroller unit, when executing the instructions in the program memory, is configured to:
cause the sensor to detect a signal according an external stimulus;
process the detected signal to obtain a processed data set and communicate the processed data set to the CNN logic circuit;
instruct the CNN logic circuit to read trained parameters from the plurality of non-volatile random access memory cells and to forward propagate the processed data set via multiple propagation paths through the multiple neurons in parallel to obtain output label data for the processed data set;
process the output label data into a control signal; and
control the actuator circuitry according to the control signal.

2. The device of claim 1, wherein the plurality of non-volatile random access memory cells comprises magnetic random access memory cells (MRAM cells).

3. The device of claim 2, wherein at least one of the MRAM cells comprises a spin torque transfer type of MRAM cell.

4. The device of claim 2, wherein the MRAM cells are of at least two different cell sizes.

5. The device of claim 2, wherein the MRAM cells are arranged with at least two different pitches.

6. The device of claim 1, wherein a read access time for the plurality of non-volatile random access memory cells by the CNN logic circuit is faster than 5 nanoseconds.

7. The device of claim 1, wherein the plurality of non-volatile random access memory cells are programmed with the full set of trained parameters for the CNN model at one of a wafer level, a chip level, or a printed circuit board level.

8. The device of claim 1, wherein the sensor comprises an image sensor and the processed data set comprises at least one two dimensional array of pixel values.

9. The device of claim 8, further comprising an optical lens assembly for imaging an object field external to the device onto the image sensor.

10. The device of claim 8, wherein the image sensor comprises a CMOS active sensor matrix.

11. The device of claim 10, wherein the image sensor is integrated on the same semiconductor substrate for the CNN logic circuit with the plurality of non-volatile random access memory cells.

12. The device of claim 11, wherein the CMOS active sensor matrix is fabricated over the plurality of non-volatile random access memory cells.

13. The device of claim 12, wherein the plurality of non-volatile random access memory cells are fabricated over the CNN logic circuit and the CNN logic circuit is fabricated over the same semiconductor substrate.

14. The device of claim 11, wherein the CNN logic circuits and the plurality of non-volatile random access memory cells are fabricated on different areas of the same semiconductor substrate, and the CMOS active sensor matrix is fabricated over the CNN logic circuits and the plurality of non-volatile random access memory cells.

15. The device of claim 11, wherein the plurality of non-volatile random access memory cells comprise MRAM cells.

16. The device of claim 1, wherein the plurality of non-volatile random access memory cells comprises MRAM cells and static random access memory (SRAM) cells.

17. The device of claim 1, wherein the plurality of non-volatile random access memory cells comprises MRAM cells and resistive random access Memory (RRAM) cells.

18. The device of claim 1, wherein the plurality of non-volatile random access memory cells comprises MRAM cells and phase change random access memory (PCRAM) cells.

19. The device of claim 1, wherein the plurality of non-volatile random access memory cells comprises MRAM cells and at least a plurality of one time programmable (OTP) memory cells.

20. A self-contained device, comprising:
a convolutional neural network (CNN) logic circuit;
a memory comprising a plurality of non-volatile magnetic random access memory (MRAM) cells, the memory storing a set of instructions and a full set of trained parameters for a CNN model containing multiple neurons;
a sensor;
an actuator circuitry; and
a microcontroller unit in communication with the memory, the sensor, the CNN logic circuit, and the actuator circuitry,
wherein the microcontroller unit, when executing the set of instructions in the memory, is configured to:
cause the sensor to detect a signal according an external stimulus;
process the detected signal to obtain a processed data set and communicate the processed data set to the CNN logic circuit;
instruct the CNN logic circuit to read trained parameters from the plurality of non-volatile MRAM cells and to forward propagate the processed data set via multiple propagation paths through the multiple neurons in parallel to obtain output label data for the processed data set;
process the output label data into a control signal; and
control the actuator circuitry according to the control signal.
